(19) United States
(12) Patent Application Publication
(10) Pub. No.: US 2016/0322429 A1
(43) Pub. Date: Nov. 3, 2016

(54) DISPLAY DEVICE STRUCTURE AND MANUFACTURING METHOD THEREOF

(71) Applicant: EverDisplay Optronics (Shanghai) Limited, Shanghai (CN)

(72) Inventors: Jr-Hong CHEN, Shanghai (CN); Weisheng SU, Shanghai (CN); Qiguo ZHANG, Shanghai (CN)

(21) Appl. No.: 15/138,714

(22) Filed: Apr. 26, 2016

(30) Foreign Application Priority Data
Apr. 28, 2015 (CN) 201510212945.4

(51) Int. Cl. H01L 27/32; H01L 51/52; H01L 51/56; G06F 3/041

(52) U.S. Cl. CPC H01L 27/323; G06F 3/0412; H01L 27/3246; H01L 27/3248; H01L 51/5275; H01L 51/56; G06F 2203/04103; H01L 2227/323

(57) ABSTRACT

The invention relates to the field of OLED display technology, more particularly, to a display device structure and manufacturing method thereof applied to an AMOLED device; the technical solution of the invention is mainly to form a drive electrode between the PLN layer and the pixel design layer in the sensing area namely the area of the forming sensor, and sets an insulation layer and sensing electrode above the top of the pixel design layer; thereby the drive electrode, the insulation layer and the sensing electrode form an embedded sensor, therefore the technical solution of the invention can effectively solve the technical problems of the difficulty of alignment, Mura and the complicated integrated lead, and reduce the thickness of the screen and the structural design difficulty of the terminal products.

### CROSS-REFERENCE TO RELATED APPLICATIONS

The present application claims priority to and the benefit of Chinese Patent Application No. CN 201510212945.4, filed on Apr. 28, 2015, the entire content of which is incorporated herein by reference.

### BACKGROUND OF THE INVENTION

1. Field of the Invention

The invention relates to the field of OLED display technology, more particularly, to a display device structure and manufacturing method thereof applied to AMOLED device.

2. Description of the Related Art

Currently, in the manufacturing process of the touch display device, it generally uses “In-cell” or “on-cell” mode for integration operation of the touch panel and the liquid crystal panel.

Wherein, on-cell touch technology is a method of embedding touch panel between the color filter substrate and the polarizing film of the display screen, namely configuring touch sensor on LCD panel; In-cell touch technology is to embed the function of the touch panel to LCD pixels, namely integrating the entire touch components into the display panel to combine the display device and the touch device as a whole, thus effectively reducing the thickness of the screen and the structural design difficulty of the terminal product.

However, since the In-cell technology requires embedding touch sensors into the pixels of the thin film transistor (TFT) array substrate, thus making the manufacturing process more complicated, reduces the yield of product, and also reducing the area for display, thus it will lead to the deterioration of the quality of the display device, Especially in the AMOLED (Active Matrix/Organic Light Emitting Diode) display technology, the pixel driving circuit structure is more complex, and generally includes 6T1C (circuit structure composed of six transistors and a capacitor) or 7TIC (circuit structure composed of 7 transistors and a capacitor), thus making the integration (IC) lead complex, the process more difficult and the cost of the process higher.

In addition, the current AMOLED are using self-luminous technology, though it may be done by forming touch sensor on encapsulation glass, it will still cause defects of Mura of the display device and the difficulty of alignment due to the mutual interference of light.

Therefore, a new technology solution to overcome the above-mentioned technical problems becomes a research direction of those skilled in the field.

### BRIEF DESCRIPTION OF THE INVENTION

In view of the deficiencies of the prior art, the technical solution of the invention provides a display device structure and manufacturing method thereof applied to an AMOLED device, the technical solution can effectively solve the defects of the difficulty of alignment, Mura, complicated Integrated lead and big process cost of the display device of the prior art.

The technical solution of the invention used to solve the above technical problem is:

A display device structure, comprising:

a substrate, provided with a display area and a sensing area;

a planarization layer, disposed on the substrate;

an OLED module located above the display area and disposed on an upper surface of a portion of the planarization layer;

a drive electrode located above the sensing area and disposed on an upper surface of a portion of the planarization layer;

a pixel design layer, covering the drive electrode and the planarization layer not covered by the drive electrode;

an insulation layer located above the pixel design layer; and

a sensing electrode, disposed on the insulation layer, combining with the insulation layer and the drive electrode to form a sensor.

Preferably, the above display device structure, Wherein the insulation layer is made from dielectric material.

Preferably, the above display device structure, wherein the OLED module includes:

an anode disposed over the planarization layer of the display area;

an OLED device layer disposed over the anode; and

a cathode disposed over the OLED device layer.

Preferably, the above display device structure, wherein the drive electrode and the anode are made from same material.

Preferably, the above display device structure, wherein the display device further comprises an index matching layer;

The index matching layer is disposed over an upper surface of the cathode.

Preferably, the above display device structure, wherein the index matching layer is made from organic compound.

Preferably, the above display device structure, wherein the substrate is a TFT array substrate.

Preferably, the above display device structure, wherein the display device is an AMOLED display.

A method for manufacturing a display device, comprising:

providing a semiconductor substrate, having a display area and a sensing area;

depositing a planarization layer above the semiconductor substrate;

forming an anode on an upper surface of the planarization layer over the display area, and forming a drive electrode on a portion of an upper surface of the planarization layer over the sensing area;

forming an OLED device layer on an upper surface of the anode, and forming a pixel design layer on an exposed surface of the planarization layer and the drive electrode;

forming a cathode covering an upper surface of the OLED device layer, an upper surface of the pixel design layer and a side wall of the pixel design layer; and

configuring an opening on the cathode to the pixel design layer, then forming the insulation layer and the sensing electrode in the opening according to the order of bottom-up.

Preferably, the above method for manufacturing the display device, wherein using a same etching process to form the drive electrode and the anode.

The above technical solution has the following advantages or beneficial effects:

The invention discloses a display device structure and manufacturing method thereof, mainly including a substrate, a planarization layer above the substrate, an OLED module above the planarization layer, a drive electrode and an insulation layer and a sensing electrode located above the top of the pixel design layer of the drive electrode, the technical solution of the invention forms a drive electrode between the planarization layer and the pixel design layer in the sensing area namely the area of the forming sensor, and sets insulation layer and sensing electrode above the top of the pixel design layer, thereby the drive electrode, the insulation layer and the sensing electrode forming an embedded sensor, therefore the technical solution of the invention can effectively solve the technical problems of the difficulty of alignment, Mura and complicated integrated lead, reduce the thickness of the screen and the structural design difficulty of the terminal products.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a schematic diagram of the display device structure of the embodiment of the invention;

FIG. 2 is a flow diagram of the method for manufacturing the display device of the embodiment of the invention.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

In order to solve the defects of the difficulty of alignment, Mura, complicated integrated lead and big process cost of the display device of the prior art, the invention provides a new display device structure and manufacturing method thereof, the technical solution can effectively solve the technical problems of alignment, Mura and complicated integrated lead and reduce the thickness of the screen and the structural design difficulty of the terminal products.

### Embodiment One

A display device structure provided in the embodiment of the invention, such as AMOLED display, mainly comprising:

a substrate, provided with a display area and a sensing area;

a planarization layer (PLN), disposed on the substrate;

an OLED module, located above the display area and disposed on an upper surface of a portion of the planarization layer;

a drive electrode (Tx) located above the sensing area and disposed on an upper surface of a portion of the planarization layer;

a pixel design layer (PDL) covering the drive electrode and the planarization layer not covered by the drive electrode;

an insulation layer, located above the pixel design layer;

a sensing electrode (Rx), disposed on the insulation layer, combining with the insulation layer and the drive electrode to form a sensor.

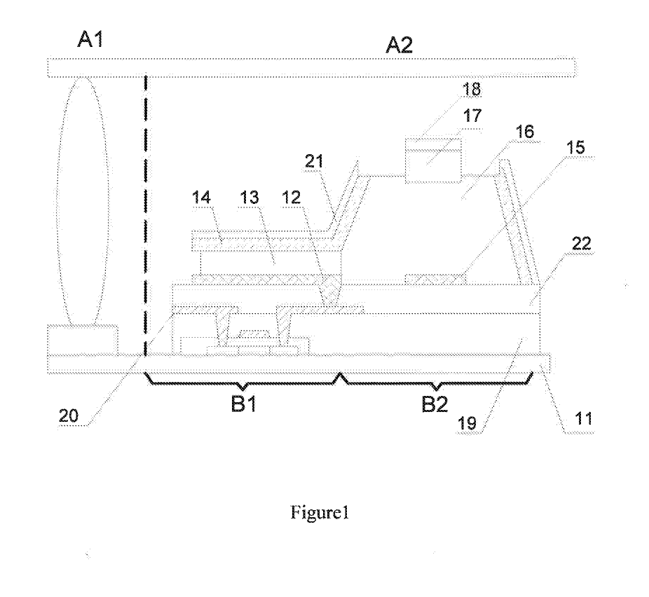

Specifically, referring to FIG. 1, the display device structure defines a packaging area A1 and an active area (AA area) A2, the substrate 11 in the active area A2 is provided with a display area 131 and a sensing area B2, the display area is configured to form the OLED module, the sensing area is configured to form a sensor.

In an alternative but non-limiting embodiment of the invention, preferably the substrate 11 is a TFT array substrate.

The substrate 11 is provided with an insulating layer 19, and the upper surface of the insulating layer 19 located on the display area B1 is also provided with signal wires 20; the signal wires 20 respectively vertically cross throughout the insulating layer 19 to the source and the drain of the substrate 11, and form electrical contact. The upper surface of the signal wires 20 and the remaining insulating layer 19 is also covered by PLN layer 22; as shown in FIG. 1, the PLN layer 22 located on the display area B1 is provided with a groove, the groove crosses throughout the PLN layer 22 and exposes the top surface of the signal wires 20 to fill with the anode material and lead out the signal wires 20.

Referring to the structure shown in FIG. 1, the upper surface of the PLN layer 22 located on the display area B1 is provided with the OLED module, and the upper surface of the PLN layer 22 located on the sensing area B2 is provided with the Tx15. Wherein, the OLED module comprises: the anode 12, the OLED device layer 13 and the cathode 14.

The anode 12 is disposed on the top surface of the PLN layer 22 located on the display area B1, and the anode 12 fills the groove located in the PLN layer 22 to further lead out the signal wires 20;

The OLED device layer 13 is disposed on the upper surface of the anode 12, and is mainly used as light-emitting layer of the display device in the embodiment of the invention.

The cathode 14 is disposed on the surface of the OLED device layer 13, and forms the above-described structure of the OLED module together with the OLED device layer 13 and the anode 12.

In an alternative but non-limiting embodiment of the invention, preferably, the anode 12 and Tx15 are made from the same material.

The exposed upper surface of the PLN layer 22 located on the sensing area and the upper surface and the side wall of Tx are covered by a thick PDL layer 16, and the top of the PDL layer 16 has a shallow opening, which is provided with an insulation layer 17, wherein, the thickness of the insulation layer 17 is preferably greater than the depth of the opening, i.e., a portion of the insulation layer 17 extrudes from the top of PDL layer 16 for forming the sensor in subsequent. Rx18 (i.e., the sensing electrode 18) is also provided over the insulation layer 17, the Rx18 is used as the other electrode of the capacitive touch sensor.

In the embodiment of the invention, preferably, the insulation layer 17 is made from insulating material.

Further, in the display device structure of the embodiment of the invention, the side wall of the PDL layer 16 is also covered by the cathode 14, and the display device further comprises an index matching layer (IMI) 21, the index matching layer 21 covers the top surface of the cathode 14, preferably, the index matching layer 21 is made from organic compound.

Wherein, in the display device, the drive electrode, the insulation layer and the sensing electrode together form the sensor, and achieve embedding the function of touch sensor into the pixels of the TFT array substrate in-cell technology, and further, the integration of the display device and the touch device.

### Embodiment Two

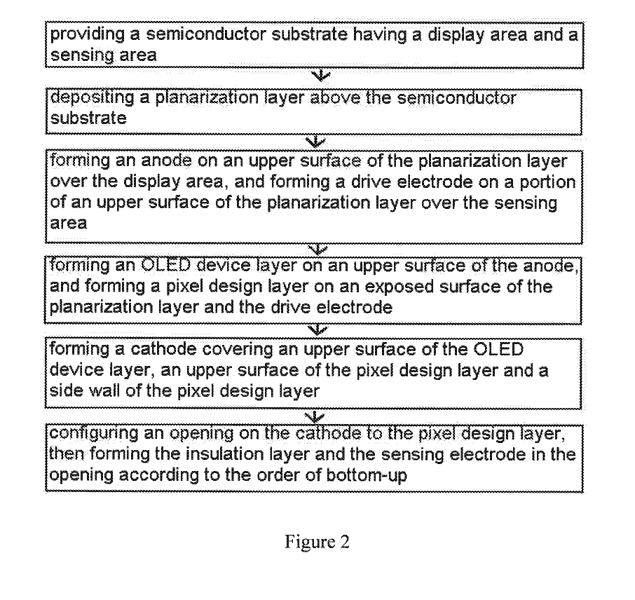

The invention also provides a method for manufacturing a display device, as shown in FIG. 2, which specifically includes:

Step S1, providing a semiconductor substrate, having a display area and a sensing area.

Wherein the semiconductor substrate mainly includes a substrate 11 having a display area B1 and a sensing area B2, the substrate 11 is provided with an insulating layer 19, and the upper surface of the insulating layer 19 located on the display area B1 is also provided with signal wires 20; the signal wires 20 respectively vertically cross throughout the insulating layer 19 to the source and the drain of the substrate 11, and form electrical contact.

Step S2, depositing a PLN layer 22 above the semiconductor substrate and configuring a groove in the PLN layer 22 located on the display area B1.

Step S3, forming an anode 12 on the upper surface of the PLN layer 22 over the display area B1, and forming Tx15 on a portion of the upper surface of the PLN layer 22 over the sensing area.

Wherein the anode 12 also fills the groove in the PLN layer 22 and further leads out the signal wires 20.

In this step, the same etching process to form the drive electrode and the anode is used, for example: using metal organic chemical vapor deposition (MOCVD) to deposit a metal layer on the upper surface of the PLN layer 22, then etching the metal layer to form the anode 12 located on the surface of the PLN layer 22 over the display area B1 and the Tx15 located on the upper surface of the PLN layer 22 over the sensing area B2, Wherein the Tx15 is used as one electrode of the capacitive touch sensor in the later step of forming sensor.

Step S4, forming an OLED device layer 13 on the upper surface of the anode 12, and forming a pixel design layer 16 on the exposed surface of the PLN layer 22 and the Tx15;

Step S5, forming a cathode 14 covering the upper surface of the OLED device layer 13, the upper surface the pixel design layer 16 and the side wall of the pixel design layer 16.

Wherein, the anode 12, the OLED device layer 13, and the cathode 14 together form the OLED module of the embodiment of the invention.

Step S6, configuring an opening on the cathode 14 to the pixel design layer 16, then forming the insulation layer 17 and the Rx18 in the opening according to the order of bottom-up to form the structure shown in FIG. 1, wherein, the Tx, the insulation layer and the Rx together form the sensor.

An embodiment of the invention further comprises a step of depositing index matching layer 21 on the upper surface of the cathode, then forming the opening and forming the insulation layer 17 and the Rx18. Preferably, the index matching layer is made from organic compound.

Of course, in the embodiment of the invention, the method for manufacturing the display device can also be understood as configuring an opening on the cathode in the area the sensor fanned namely the sensing area, using the way such as FMM (fine metal mask) etc., and depositing an insulating layer as the insulation layer, meanwhile using the metal in AE2 or AE3 layer to form the Tx metal layer while forming the anode, and finally forming the corresponding sensor. Therefore, the technical solution of the invention can. embed the function of the touch sensor into the pixels on the TFT array substrate with in-cell technology, thus achieving the integration of display device and touch device, and avoid the complex of integrated leads and design structure while making the screen of the display device slimmer.

In summary, the invention discloses a display device structure and manufacturing method thereof, mainly including the substrate, the PLN layer above the substrate, the OLED module and the drive electrode above the PLN layer, and the insulation layer and sensing electrode located above the top of the pixel design layer of the drive electrode; the technical solution of the invention is mainly to form a drive electrode between the PLN layer and the pixel design layer in the sensing area namely the area forming sensor, and sets the insulation layer and the sensing electrode above the top of the pixel design layer; thereby the drive electrode, the insulation layer and the sensing electrode form an embedded sensor, therefore the technical solution of the invention can effectively solve the technical problems of difficulty of alignment, Mura and integrated lead complication, and reduce the thickness of the screen and the structural design difficulty of the terminal products.

The foregoing is only the preferred embodiments of the invention, not thus limiting embodiments and scope of the invention, those skilled in the art should be able to realize that the schemes obtained from the content of specification and figures of the invention are within the scope of the invention.

What is claimed is:

1. A display device structure, comprising:
a substrate, provided with a display area and a sensing area;
a planarization layer, disposed on the substrate;
an OLED module, located above the display area and disposed on an upper surface of a portion of the planarization layer;
a drive electrode located above the sensing area and disposed on an upper surface of a portion of the planarization layer;
a pixel defining layer, covering the drive electrode and the planarization layer not covered by the drive electrode;
an insulation layer, located above the pixel defining layer; and
a sensing electrode, disposed on the insulation layer, combining with the insulation layer and the drive electrode to form a sensor.

2. The display device structure of claim 1, wherein the insulation layer is made from dielectric material.

3. The display device structure of claim 1, wherein the OLED module includes:
an anode, disposed over the planarization layer of the display area;
an OLED device layer, disposed over the anode; and
a cathode, disposed over the OLED device layer.

4. The display device structure of claim 3, wherein the drive electrode and the anode are made from same material.

5. The display device structure of claim 3, wherein the display device further comprises an index matching layer;
the index matching layer is disposed over an upper surface of the cathode.

6. The display device structure of claim 5, wherein the index matching layer is made from organic compound.

7. The display device structure of claim 1, wherein the substrate is a TFT array substrate.

8. The display device structure of claim 1, wherein the display device is an AMOLED display.

9. A method for manufacturing a display device, comprising:
providing a semiconductor substrate having a display area and a sensing area;
depositing a planarization layer above the semiconductor substrate;
forming an anode on an upper surface of the planarization layer over the display area, and forming a drive electrode on a. portion of an upper surface of the planarization layer over the sensing area;
forming an OLED device layer on an upper surface of the anode, and forming a pixel design layer on an exposed surface of the planarization layer and the drive electrode;
forming a cathode covering an upper surface of the OLED device layer, an upper surface of the pixel design layer and a side wall of the pixel design layer; and
configuring an opening on the cathode to the pixel design layer, then forming the insulation layer and the sensing electrode in the opening according to the order of bottom-up.

10. The method for manufacturing the display device of claim 9, wherein, using a same etching process to form the drive electrode and the anode.
